(19) United States
(12) Patent Application Publication
(10) Pub. No.: US 2024/0162132 A1
(43) Pub. Date: May 16, 2024

(54) FAN-OUT SEMICONDUCTOR PACKAGE

(71) Applicant: SAMSUNG ELECTRONICS CO., LTD., Suwon-s (KR)

(72) Inventor: Kwangsoo KIM, Suwon-si (KR)

(73) Assignee: SAMSUNG ELECTRONICS CO., LTD., Suwon-s (KR)

(21) Appl. No.: 18/384,152

(22) Filed: Oct. 26, 2023

(30) Foreign Application Priority Data
Nov. 11, 2022 (KR) 10-2022-0150989
Feb. 14, 2023 (KR) 10-2023-0019536

(51) Int. Cl. H01L 23/498; H01L 23/00; H01L 25/10

(52) U.S. Cl. CPC H01L 23/49822; H01L 23/49838; H01L 24/16; H01L 25/105; H01L 24/48; H01L 2224/16227; H01L 2224/16238; H01L 2224/48229; H01L 2225/1023; H01L 2225/1041; H01L 2225/1058; H01L 2924/15174; H01L 2924/182

(57) ABSTRACT

Provided is a semiconductor package including a semiconductor chip, a connection structure below the semiconductor chip and electrically connected to the semiconductor chip, and an external connection terminal below the connection structure, wherein the connection structure includes a first via array including a plurality of first vias in a first direction, a second via array above the first via array and including a plurality of second vias in the first direction, and a first pad between the first via array and the second via array and on upper surfaces of the plurality of the first vias, wherein the second via array is offset from the first via array in the first direction and does not overlap the first via array in a vertical direction.

### CROSS-REFERENCE TO RELATED APPLICATION

This application is based on and claims priority to Korean Patent Application No. 10-2022-0150989, filed on Nov. 11, 2022, and 10-2023-0019536, filed on Feb. 14, 2023, in the Korean Intellectual Property Office, the disclosures of which are incorporated by reference herein in their entireties.

### BACKGROUND

Embodiments of the present disclosure relate to a semiconductor package, and more particularly, to a fan-out semiconductor package.

In order to improve performance of semiconductor packages, it is necessary to increase the number of external connection terminals of the semiconductor packages. However, in order to increase the number of external connection terminals, it is necessary to increase planar areas of the semiconductor packages. On the other hand, in order to reduce manufacturing costs, it is necessary to reduce the planar area of each of the semiconductor chips. In order to package a semiconductor chip with a reduced size while securing a sufficient planar area of the semiconductor package for the increased number of external connection terminals, a fan-out package has been developed. In the fan-out package, the semiconductor chip is connected to external connection terminals using a connection structure having a planar area larger than that of the semiconductor chip.

### SUMMARY

One or more embodiments provide a semiconductor package having improved reliability by including a redistribution layer in which a plurality of vias are in contact with a single pad.

According to an aspect of an embodiment, there is provided a semiconductor package including a semiconductor chip, a connection structure below the semiconductor chip and electrically connected to the semiconductor chip, and an external connection terminal below the connection structure, wherein the connection structure includes a first via array including a plurality of first vias in a first direction, a second via array above the first via array and including a plurality of second vias in the first direction, and a first pad between the first via array and the second via array and on upper surfaces of the plurality of the first vias, wherein the second via array is offset from the first via array in the first direction and does not overlap the first via array in a vertical direction.

According to another aspect of an embodiment, there is provided a semiconductor package including a semiconductor chip, and a connection structure below the semiconductor chip and electrically connected to the semiconductor chip, wherein the connection structure includes a plurality of first vias in a first direction, a plurality of second vias in the first direction above the plurality of first vias, a first pad between the plurality of first vias and the plurality of second vias and on upper surfaces of the plurality of first vias, a second pad between the plurality of first vias and the plurality of second vias and on lower surfaces of the plurality of second vias, and a redistribution pattern between the first pad and the second pad in the first direction, wherein the plurality of second vias are offset from the plurality of first vias in the first direction and does not overlap the plurality of first vias in a vertical direction.

According to another aspect of an embodiment, there is provided a semiconductor package including a semiconductor chip, a connection structure below the semiconductor chip and electrically connected to the semiconductor chip, a solder ball below the connection structure, a pad below the semiconductor chip and electrically connected to the semiconductor chip, a conductive post adjacent to the semiconductor chip, and an encapsulation layer on the semiconductor chip and the conductive post, wherein the connection structure includes a first via array including a pair of first vias in a first direction, a second via array above the first via array and including a pair of second vias in the first direction, a first pad between the first via array and the second via array, integrally formed with upper surfaces the pair of first vias, and extending in the first direction, a second pad between the first via array and the second via array and in contact with lower surfaces of the pair of second vias, and a redistribution insulating layer in which the first via array, the second via array, the first pad, and the second pad are buried, wherein the second via array is offset from the first via array in the first direction and does not overlap the first via array in a vertical direction, wherein an upper surface of the first pad and an upper surface of the second pad are at a same vertical level, and wherein a distance between the pair of first vias is greater than a distance by which the second via array is offset from the first via array in the first direction.

### BRIEF DESCRIPTION OF DRAWINGS

Embodiments will be more clearly understood from the following detailed description taken in conjunction with the accompanying drawings in which:

FIG. 1 is a cross-sectional view showing a semiconductor package according to an embodiment;

FIG. 2 is an enlarged view showing a portion of a redistribution layer of the semiconductor package illustrated in FIG. 1;

FIG. 3 is a plan view in which a portion of the redistribution layer illustrated in FIG. 2 is viewed in the vertical direction;

FIG. 4 is a cross-sectional view showing a semiconductor package according to another embodiment;

FIG. 5 is an enlarged view showing a portion of a redistribution layer of the semiconductor package illustrated in FIG. 4;

FIG. 6 is a plan view in which a portion of the redistribution layer illustrated in FIG. 5 is viewed in the vertical direction;

FIG. 7 is a cross-sectional view showing a semiconductor package according to another embodiment;

FIG. 8 is an enlarged view showing a portion of a redistribution layer of the semiconductor package illustrated in FIG. 7;

FIG. 9 is a plan view in which a portion of the redistribution layer illustrated in FIG. 8 is viewed in the vertical direction;

FIG. 10 is a cross-sectional view showing a semiconductor package according to another embodiment;

FIG. 11 is a cross-sectional view showing a semiconductor package according to another embodiment;

FIG. 12 is a cross-sectional view showing a semiconductor package according to another embodiment;

FIG. 13 is a plan view in which a portion of an upper redistribution layer illustrated in FIG. 12 is viewed in the vertical direction; and

FIGS. 14, 15, 16, 17, 18, 19, and 20 are cross-sectional views illustrating a manufacturing process of the semiconductor package illustrated in FIGS. 1 to 3.

### DETAILED DESCRIPTION OF EMBODIMENTS

Hereinafter, embodiments are described in detail with reference to the accompanying drawings. The embodiments may, however, be embodied in different forms and should not be constructed as limited to the embodiments set forth herein. Embodiments described herein are example embodiments, and thus, the disclosure is not limited thereto.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

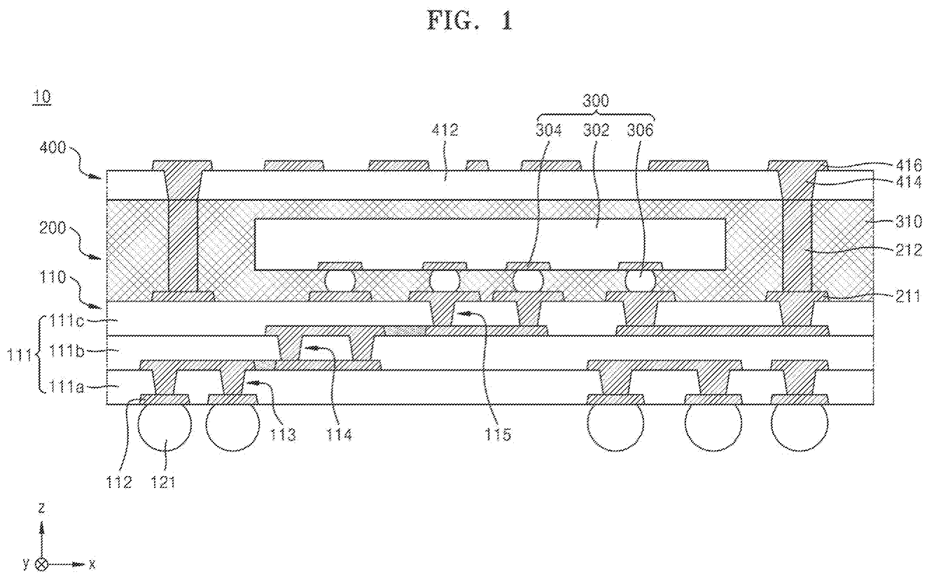

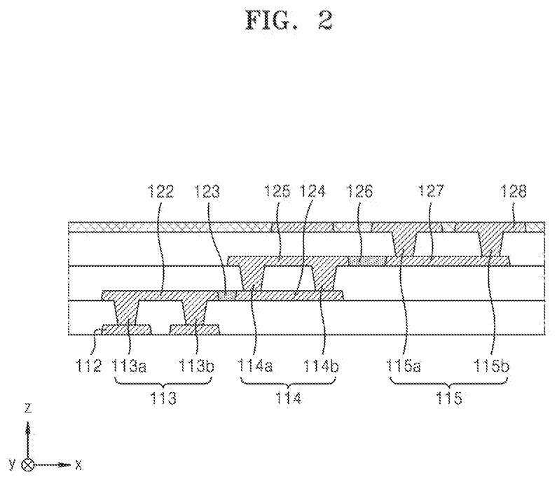

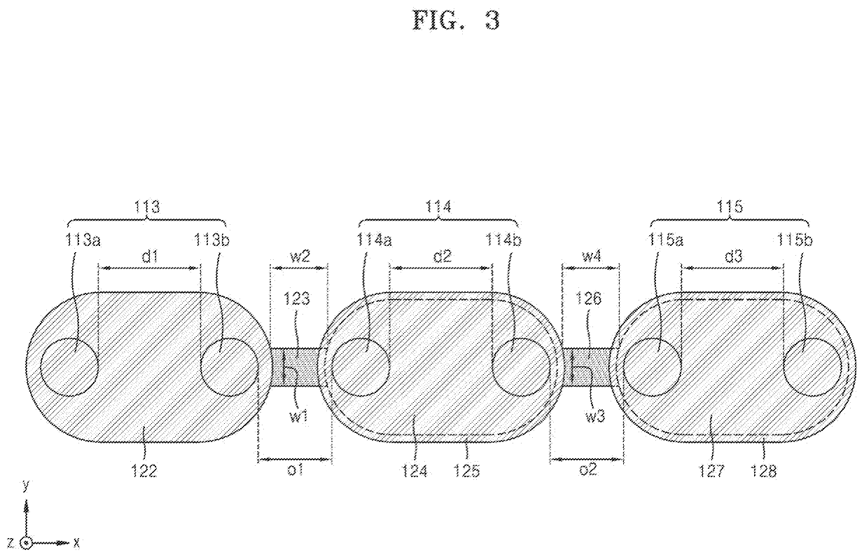

FIG. 1 is a cross-sectional view showing a semiconductor package according to an embodiment, and FIG. 2 is an enlarged view showing a portion of a redistribution layer of the semiconductor package illustrated in FIG. 1. Also, FIG. 3 is a plan view in which a portion of the redistribution layer illustrated in FIG. 2 is viewed in the vertical direction.

Referring to FIG. 1, a semiconductor package 10 may include the lower connection structure 110, a first semiconductor chip 300 on an upper surface of the lower connection structure 110, an intermediate connection structure 200 on the upper surface of the lower connection structure 110, and an upper connection structure 400 on the first semiconductor chip 300 and the intermediate connection structure 200. In some embodiments, the semiconductor package 10 may further include an encapsulation layer 310 between the lower connection structure 110 and the upper connection structure 400. In some embodiments, the semiconductor package 10 may further include an external connection terminal 121 on a lower surface of the lower connection structure 110.

The lower connection structure 110 may be configured to connect the first semiconductor chip 300 to the external connection terminal 121, connect the intermediate connection structure 200 to the first semiconductor chip 300, and connect the intermediate connection structure 200 to the external connection terminal 121. The lower connection structure 110 may include one or more lower insulating layers 111a, 111b, and 111c (a first lower insulating layer 111a, a second lower insulating layer 111b, and a third lower insulating layer 111c), one or more lower redistribution pads 122, 124, 125, and 127 (a first pad 122, a second pad 124, a third pad 125, and a fourth pad 127 or simply referred to as pads 122, 124, 125, and 127) on the lower insulating layers 111a, 111b, and 111c, and one or more lower vias 113a, 113b, 114a, 114b, 115a, and 115b (first lower vias 113a and 113b, second lower vias 114a and 114b, and third lower vias 115a and 115b) that pass through the lower insulating layers 111a, 111b, and 111c and come into contact with the lower redistribution pads 122, 124, 125, and 127. The one or more lower redistribution pads 122, 124, 125, and 127 and the one or more lower vias 113a, 113b, 114a, 114b, 115a, and 115b may provide an electrical path for connecting the first semiconductor chip 300 to the external connection terminal 121, an electrical path for connecting the intermediate connection structure 200 to the first semiconductor chip 300, and an electrical path for connecting the intermediate connection structure 200 to the external connection terminal 121. The lower connection structure 110 may include a redistribution structure or a printed circuit board (PCB).

Hereinafter, the lower connection structure 110 is described in more detail. Descriptions thereof are given with reference to FIGS. 2 and 3.

Here, two directions substantially parallel to the upper surfaces of the first to third lower insulating layers 111a, 111b, and 111c are defined as a first direction (x direction) and a second direction (y direction), and a direction substantially perpendicular to the upper surface of the third lower insulating layer 111c is defined as a third direction (z direction). The first direction (x direction) and the second direction (y direction) may be substantially perpendicular to each other. A vertical direction may be a direction substantially parallel to a third direction (z direction), and a vertical level may be a height from a reference plane (e.g., the lower surface of the third lower insulating layer 111c) in the third direction (z direction). Also, a horizontal direction may be the first direction (x direction), the second direction (y direction), or a direction that is perpendicular to the third direction (z direction) and inclined relative to the first and second directions (x and y directions). Hereinafter, definitions of directions in all drawings are the same as those in FIGS. 1 to 3 unless otherwise noted.

The lower connection structure 110 may include a first lower via array 113, a second lower via array 114, and a third lower via array 115 which are provided at different vertical levels.

According to an embodiment, the first lower via array 113 may include a plurality of first lower vias 113a and 113b arranged in the first direction (x direction). Here, the drawing illustrates that two first lower vias 113a and 113b are included in the first lower via array 113, but embodiments are not limited thereto. According to an embodiment, three or more first lower vias 113a and 113b may be included in the first lower via array 113. The first lower via array 113 may be formed through the first lower insulating layer 111a.

According to an embodiment, the second lower via array 114 may include a plurality of second lower vias 114a and 114b arranged in the first direction (x direction). Here, the drawing illustrates that two second lower vias 114a and 114b are included in the second lower via array 114, but embodiments are not limited thereto. According to an embodiment, three or more second lower vias 114a and 114b may be included in the second lower via array 114. The second lower via array 114 may be formed through the second lower insulating layer 111b.

The lower connection structure 110 may include a first pad 122 which is at a vertical level between the first lower via array 113 and the second lower via array 114 and covers the upper surface of the first lower via array 113. The first pad 122 may vertically overlap the first lower via array 113 and may cover an entire area of the upper surfaces of all the first lower vias 113a and 113b that are included in the first lower via array 113. The first pad 122 may be integrally formed with all of the first lower vias 113a and 113b that are included in the first lower via array 113.

The second lower via array 114 may be offset in the first direction (x direction) to not overlap the first lower via array 113 in the third direction (z direction). The first lower via array 113 and the second lower via array 114 having different vertical levels may be offset from each other by a first offset distance o1. During a forming process, the first lower via array 113, the second lower via array 114, and the first pad 122 may have curved and stepped portions on a horizontal plane. When the first lower via array 113 and the second lower via array 114 are formed vertically overlapping each other with the first pad 122 therebetween, a peeling phenomenon may occur at the interface with the first lower insulating layer 111a and the second lower insulating layer 111b due to the accumulation of the curved and stepped portions of the first lower via array 113, the second lower via array 114, and the first pad 122. Also, open/short circuit failures may occur between the first lower via array 113, the second lower via array 114, and the first pad 122. Therefore, the first lower via array 113 and the second lower via array 114 are spaced apart from each other by the first offset distance o1 in the first direction (x direction), to prevent the peeling and open/short circuit failures from occurring at the interface.

A distance d1 between a pair of first lower vias 113a and 113b adjacent to each other among the plurality of first lower vias 113a and 113b may be greater than the first offset distance o1 by which the second lower via array 114 is offset from the first lower via array 113 in the first direction (x direction). The first offset distance o1 by which the second via array 114 is offset from the first via array 113 in the first direction (x direction) may be, for example, about 10 micrometers to about 20 millimeters.

The lower connection structure 110 may include a second pad 124 which is at a vertical level between the first lower via array 113 and the second lower via array 114 and covers the lower surface of the second lower via array 114. The second pad 124 may vertically overlap the second lower via array 114 and may cover an entire area of the lower surfaces of all the second lower vias 114a and 114b that are included in the second lower via array 114. The upper surface of the second pad 124 may be in contact with the lower surfaces of the second lower vias 114a and 114b. According to an embodiment, the first pad 122 and the second pad 124 may be at substantially the same vertical level, but embodiments are not limited thereto.

According to an embodiment, the lower connection structure 110 may include a first redistribution pattern 123 between the first pad 122 and the second pad 124 in the first direction (x direction). The first redistribution pattern 123 may extend in the first direction (x direction) and may be integrally formed with the first pad 122 and the second pad 124. Also, the first redistribution pattern 123 may include the same material as the first pad 122 and the second pad 124. However, embodiments are not limited thereto. According to an embodiment, the first redistribution pattern 123 may include a different material from the first pad 122 and the second pad 124. A width w2 of the first redistribution pattern 123 in the first direction (x direction) may be greater than a width w1 of the first redistribution pattern 123 in the second direction (y direction). Also, as illustrated in FIG. 3, the width w1 of the first redistribution pattern 123 in the second direction (y direction) may be less than the width of each of the first pad 122 and the second pad 124 in the second direction (y direction). The first redistribution pattern 123 may provide an electrical path for connecting the first pad 122 to the second pad 124.

According to an embodiment, the third lower via array 115 may include a plurality of third lower vias 115a and 115b arranged in the first direction (x direction). Here, the drawing illustrates that two third lower vias 115a and 115b are included in the third lower via array 115, but embodiments are not limited thereto. According to an embodiment, three or more third lower vias 115a and 115b may be included in the third lower via array 115. The third lower via array 115 may be formed through the third lower insulating layer 111c.

The lower connection structure 110 may include a third pad 125 which is at a vertical level between the second lower via array 114 and the third lower via array 115 and covers an entire area of the upper surface of the second lower via array 114. The third pad 125 may vertically overlap the second lower via array 114 and may cover an entire area of the upper surfaces of all the second lower vias 114a and 114b that are included in the second lower via array 114. The third pad 125 may be integrally formed with all of the second lower vias 114a and 114b that are included in the second lower via array 114.

The third lower via array 115 may be offset in the first direction (x direction) to not overlap the second lower via array 114 in the third direction (z direction). The second lower via array 114 and the third lower via array 115 having different vertical levels may be offset from each other by a second offset distance o2. At the same time, the third lower via array 115 may be offset to not overlap the first lower via array 113 in the third direction (z direction). During a forming process, the second lower via array 114, the third lower via array 115, and the second pad 124 may have curved and stepped portions on a horizontal plane. When the second lower via array 114 and the third lower via array 115 are formed vertically overlapping each other with the third pad 125 therebetween, a peeling phenomenon may occur at the interface with the second lower insulating layer 111b and the third lower insulating layer 111c due to the accumulation of the curved and stepped portions of the second lower via array 114, the third lower via array 115, and the third pad 125. Also, open/short circuit failures may occur between the second lower via array 114, the third lower via array 115, and the third pad 125. Therefore, the second lower via array 114 and the third lower via array 115 are spaced apart from each other by the second offset distance o2, to prevent the peeling and open/short circuit failures from occurring at the interface.

A distance d2 between a pair of second lower vias 114a and 114b adjacent to each other among the plurality of second lower vias 114a and 114b or a distance d3 between a pair of third lower vias 115a and 115b adjacent to each other among the plurality of third lower vias 115a and 115b may be greater than the second offset distance o2 by which the third lower via array 115 is offset from the second lower via array 114 in the first direction (x direction). The second offset distance o2 by which the third lower via array 115 is offset from the second lower via array 114 in the first direction (x direction) may be about 10 micrometers to about 20 millimeters.

Each of the first lower vias 113a and 113b included in the first lower via array 113, the second lower vias 114a and 114b included in the second lower via array 114, and the third lower vias 115a and 115b included in the third lower via array 115 may respectively have a diameter that decreases towards the external connection terminal 121 in the vertical direction. For example, each of the first lower vias 113a and 113b, the second lower vias 114a and 114b, and the third lower vias 115a and 115b may have a tapered shape in the vertical direction.

According to an embodiment, a lower pad 112 disposed below the first lower via array 113 and electrically connected to the external connection terminal 121 may be in contact with the first lower via array 113. The lower pad 112 may be electrically connected to the first pad 122 through the first lower via array 113. In addition, the lower connection structure 110 may include a fifth pad 128 disposed on the third lower via array 115 and electrically connected to the first semiconductor chip 300, and the fifth pad 128 may cover an entire area of the upper surface of the third lower via array 115. The fifth pad 128 may be electrically connected to a fourth pad 127 through the third lower via array 115. The third lower via array 115 may be integrally formed or in contact with the fifth pad 128 electrically connected to the first semiconductor chip 300. Here, the third lower via array 115 may provide a movement path of a power signal for operating the first semiconductor chip 300 or a movement path of a ground signal for grounding the first semiconductor chip 300. However, embodiments are not limited thereto, and the third lower via array 115 may provide a movement path of a command signal and/or an address signal of the first semiconductor chip 300. Also, the third lower via array 115 may provide a movement path for signals of the first semiconductor chip 300.

The lower insulating layers 111a, 111b, and 111c may include, for example, an inorganic insulating material, an organic insulating material, or a combination thereof. The inorganic insulating material may include, for example, a silicon oxide (SiO₂), a silicon nitride (SiN), or a combination thereof. The organic insulating material may include, for example, polyimide, epoxy resin, or a combination thereof. Each of the plurality of pads 122, 124, 125, and 127 and the lower vias 113a, 113b, 114a, 114b, 115a, and 115b, which are buried inside the lower insulating layers 111a, 111b, and 111c, may include a conductive material that includes, for example, copper (Cu), gold (Au), silver (Ag), nickel (Ni), tungsten (W), aluminum (Al), or combinations thereof. In an embodiments, each of the plurality of pads 122, 124, 125, and 127 and the lower vias 113a, 113b, 114a, 114b, 115a, and 115b may further include a barrier material that prevents the conductive material from diffusing out of the plurality of pads 122, 124, 125, and 127 and the lower vias 113a, 113b, 114a, 114b, 115a, and 115b. The barrier material may include, for example, titanium (Ti), tantalum (Ta), titanium nitride (TiN), tantalum nitride (TaN), or a combination thereof.

The first semiconductor chip 300 may include a body 302 and a chip pad 304 on a lower surface of the body 302. The body 302 may include a substrate and an integrated circuit on the substrate. A surface of the first semiconductor chip 300, on which the integrated circuit is formed, may be an active surface, and a surface of the first semiconductor chip 300 on the opposite side from the active surface may be an inactive surface. In FIG. 1, the active surface of the first semiconductor chip 300 may include the lower surface of the first semiconductor chip 300 and the inactive surface of the first semiconductor chip 300 may include the upper surface of the first semiconductor chip 300. The substrate may include a semiconductor material, for example, a group IV semiconductor material, a group III-V semiconductor material, a group II-VI semiconductor material, or a combination thereof. The group IV semiconductor material may include, for example, silicon (Si), germanium (Ge), or a combination thereof. The group III-V semiconductor material may include, for example, gallium arsenide (GaAs), indium phosphide (InP), gallium phosphide (GaP), indium arsenide (InAs), indium antimonide (InSb), indium gallium arsenide (InGaAs), or a combination thereof. The group II-VI semiconductor material may include, for example, zinc telluride (ZnTe), cadmium sulfide (CdS), or a combination thereof. The integrated circuit may include any type of integrated circuit including a memory circuit, a logic circuit, or a combination thereof. The memory circuit may include a dynamic random access memory (DRAM) circuit, a static random access memory (SRAM) circuit, a flash memory circuit, an electrically erasable and programmable read-only memory (EPROM) circuit, a phase-change random access memory (PRAM) circuit, a magnetic random access memory (MRAM) circuit, a resistive random access memory (RRAM) circuit, or a combination thereof. The logic circuit may include, for example, a central processing unit (CPU) circuit, a graphics processing unit (GPU) circuit, a controller circuit, an application specific integrated circuit (ASIC) circuit, an application processor (AP) circuit, or a combination thereof.

The chip pad 304 may connect the integrated circuit of the body 302 to the lower connection structure 110. The chip pad 304 may include a conductive material that includes, for example, copper (Cu), gold (Au), silver (Ag), nickel (Ni), tungsten (W), aluminum (Al), or a combination thereof.

The intermediate connection structure 200 may be between the lower connection structure 110 and the upper connection structure 400 and connect the lower connection structure 110 to the upper connection structure 400. The intermediate connection structure 200 may be around the first semiconductor chip 300. For example, the intermediate connection structure 200 may be adjacent to and surround the first semiconductor chip 300.

The intermediate connection structure 200 may include a conductive post 212 configured to connect the lower connection structure 110 to the upper connection structure 400. The intermediate connection structure 200 may include an intermediate pattern 211 connected to the third lower vias 115a and 115b of the lower connection structure 110. The intermediate pattern 211 and the conductive post 212 may provide an electrical path for connecting the lower connection structure 110 to the upper connection structure 400.

Each of the intermediate patterns 211 and the conductive post 212 may include a conductive material that includes, for example, copper (Cu), gold (Au), silver (Ag), nickel (Ni), tungsten (W), aluminum (Al), or a combination thereof. In an embodiment, each of the intermediate patterns 211 and the conductive post 212 may further include a barrier material that prevents the conductive material from diffusing out of the intermediate patterns 211 and the conductive post 212. The barrier material may include, for example, titanium (Ti), tantalum (Ta), titanium nitride (TiN), tantalum nitride (TaN), or a combination thereof.

The encapsulation layer 310 may cover the upper surface of the first semiconductor chip 300 and the upper surface of the intermediate connection structure 200. The encapsulation layer 310 may fill a space between the first semiconductor chip 300 and the upper connection structure 400 and a space between the intermediate connection structure 200 and the upper connection structure 400. In some embodiments, a space between the intermediate connection structure 200 and the first semiconductor chip 300 and a space between the lower connection structure 110 and the first semiconductor chip 300 may be further filled at least partially. The encapsulation layer 310 may include, for example, a thermosetting resin such as an epoxy resin, a thermoplastic resin such as polyimide, or a resin formed by adding an inorganic filler to thermosetting resin or thermoplastic resin, specifically such as ABF, FR-4, and BT. Also, the encapsulation layer 310 may include a molding material such as an epoxy molding compound (EMC) or a photosensitive material such as polyimide (PI).

The upper connection structure 400 may be connected to the intermediate connection structure 200. The upper connection structure 400 may include an upper redistribution insulating layer 412 on the encapsulation layer 310, an upper redistribution pad 416 on the upper redistribution insulating layer 412, and an upper redistribution via 414 passing through the upper redistribution insulating layer 412 and extending between the conductive post 212 and the upper redistribution pad 416. The upper connection structure 400 may include a redistribution structure.

A plurality of upper redistribution pads 416 may be provided. Some of the plurality of upper redistribution pads 416 may be grounded, and the other upper redistribution pads 416 may be configured to transmit signals. At least some of the upper redistribution pads 416 are grounded, and thus, characteristics (e.g., signal integrity) of signals transmitted through the other upper redistribution pads 416 and characteristics (e.g., power integrity) of power may be improved.

Each of the upper redistribution pad 416 and the upper redistribution via 414 may include a conductive material that includes, for example, copper (Cu), gold (Au), silver (Ag), nickel (Ni), tungsten (W), aluminum (Al), or a combination thereof. In an embodiment, each of the upper redistribution pad 416 and the upper redistribution via 414 may further include a barrier material that prevents the conductive material from diffusing out of the upper redistribution pad 416 and the upper redistribution via 414. The barrier material may include, for example, titanium (Ti), tantalum (Ta), titanium nitride (TiN), tantalum nitride (TaN), or a combination thereof.

The external connection terminal 121 may be positioned on the lower surface of the lower pad 112 of the lower connection structure 110. The external connection terminal 121 may include a conductive material that includes, for example, tin (Sn), lead (Pb), silver (Ag), copper (Cu), or a combination thereof. The external connection terminal 121 may be formed using, for example, a solder ball. The external connection terminal 121 may connect the semiconductor package 10 to a circuit board, another semiconductor package, an interposer, or a combination thereof.

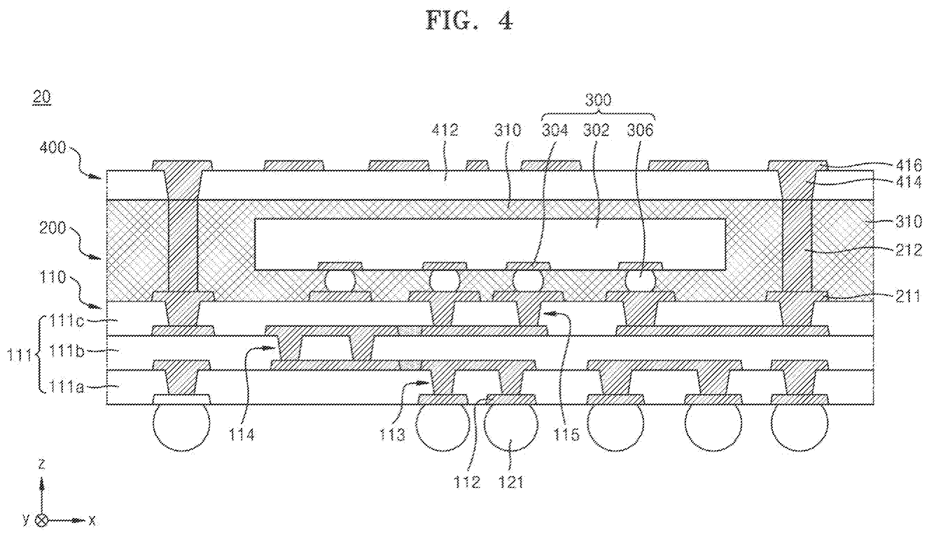

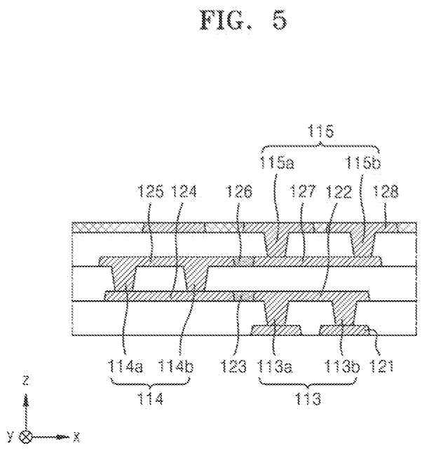

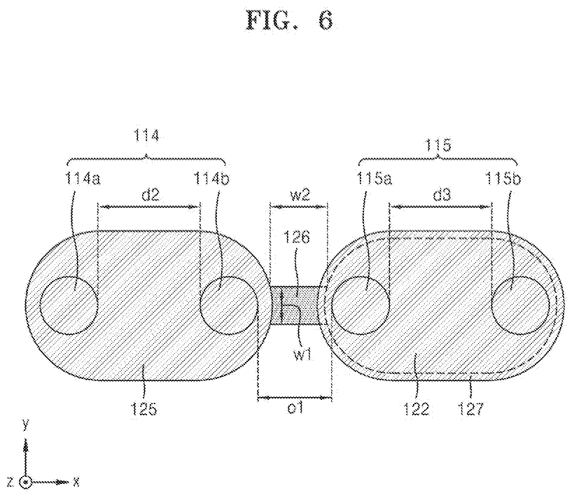

FIG. 4 is a cross-sectional view showing a semiconductor package 20 according to an embodiment, and FIG. 5 is an enlarged view showing a portion of a redistribution layer of the semiconductor package 20 illustrated in FIG. 4. Also, FIG. 6 is a plan view in which a portion of the redistribution layer illustrated in FIG. 5 is viewed in the vertical direction.

The semiconductor package 20 illustrated in FIGS. 4 to 6 is almost the same as the semiconductor package 10 illustrated in FIGS. 1 to 3, except that a third lower via array 115 overlaps at least a portion of a first lower via array 113 in a third direction (z direction). Therefore, repeated descriptions of components are omitted.

In the semiconductor package 10 illustrated in FIGS. 1 to 3, the third lower via array 115 may be offset a certain distance to not overlap the second lower via array 114 and the first lower via array 113 in the third direction (z direction). In the semiconductor package 20 illustrated in FIGS. 4 to 6, the third lower via array 115 may be offset by a certain distance to not overlap, in the third direction (z direction), the second lower via array 114 having a different vertical level than that of the third lower via array 115 but may overlap at least a portion of the first lower via array 113. Even though the third lower via array 115 overlaps at least a portion of the first lower via array 113 in the third direction (z direction), a via may not be formed overlapping the upper surface of a first pad 122 covering the upper surface of the first lower via array 113 and the upper surface of a second pad 124 covering the lower surface of the second lower via array 114. Accordingly, an interface peeling phenomenon due to accumulated curved and stepped portions of the first to third lower via arrays 113, 114, and 115 and a plurality of pads 122, 124, 125, and 127 may be prevented.

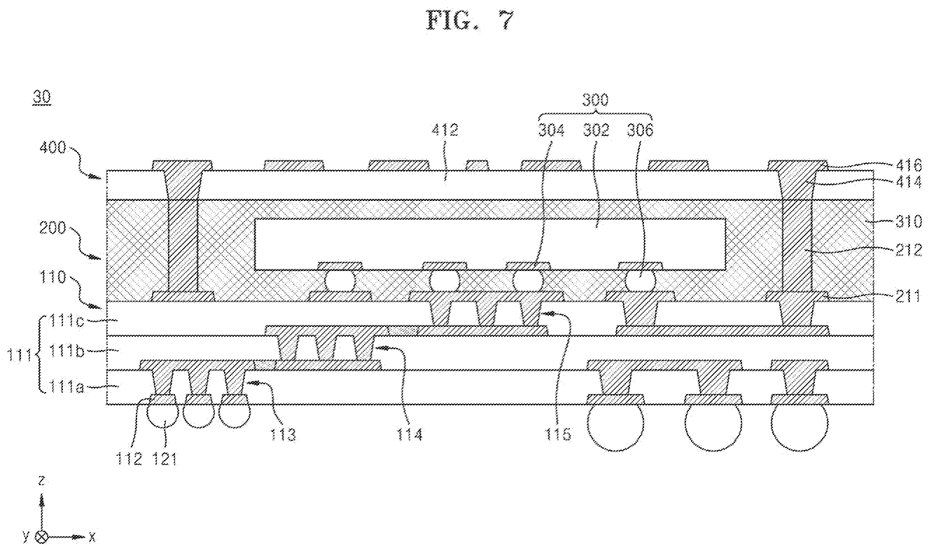

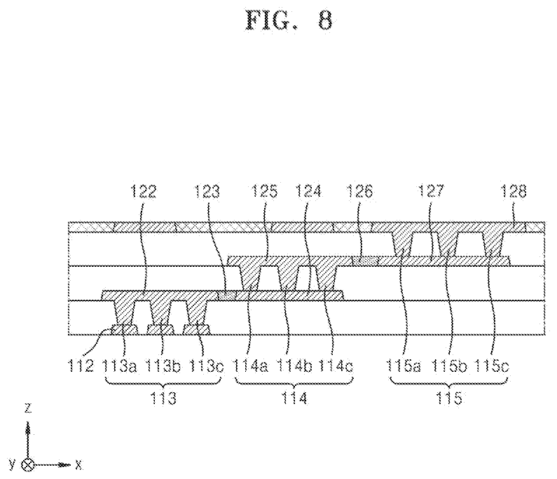

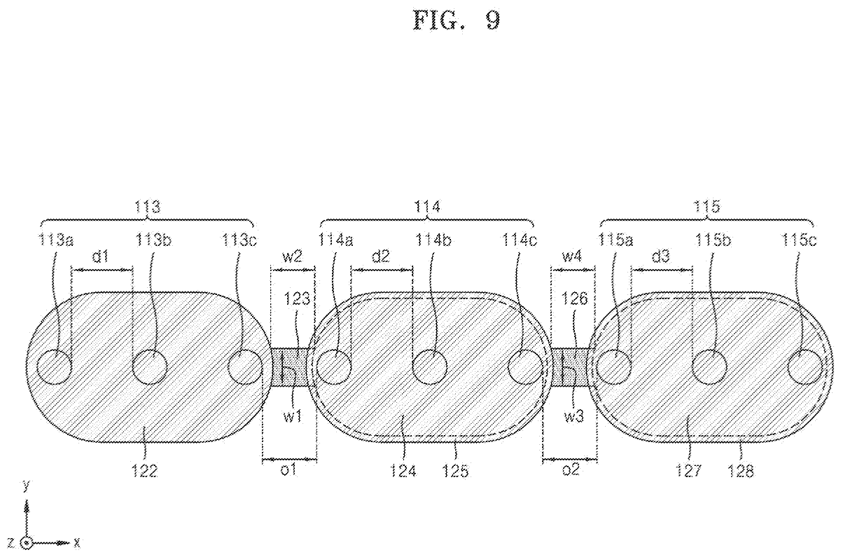

FIG. 7 is a cross-sectional view showing a semiconductor package 30 according to another embodiment. FIG. 8 is an enlarged view showing a portion of a redistribution layer of the semiconductor package 30 illustrated in FIG. 7. FIG. 9 is a plan view in which a portion of the redistribution layer illustrated in FIG. 8 is viewed in the vertical direction.

The semiconductor package 30 illustrated in FIGS. 7 to 9 is almost the same as or similar to the semiconductor package 10 illustrated in FIGS. 1 to 3, except that the number of lower vias included in each of a plurality of lower via arrays 113, 114, and 115 is different. Descriptions of the components given with reference to FIGS. 1 to 3 are omitted.

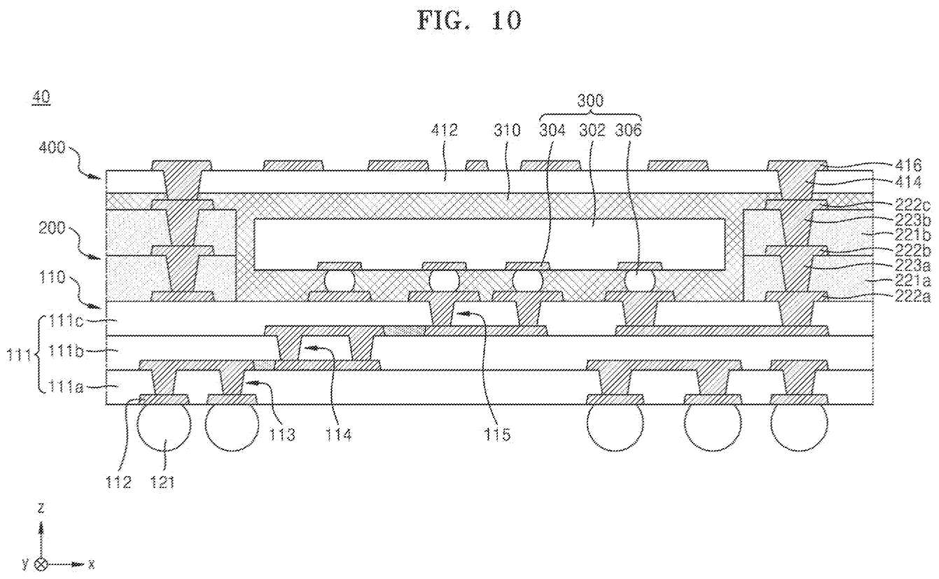

FIG. 10 is a cross-sectional view showing a semiconductor package 40 according to another embodiment. The semiconductor package 40 illustrated in FIG. 10 may include a fan-out panel level package (FOPLP). The semiconductor package 40 illustrated in FIG. 10 may be almost the same as or similar to the semiconductor package 10 illustrated in FIGS. 1 to 3, except that an intermediate connection structure 200 has a different structure. Therefore, the structure of the intermediate connection structure 200 is mainly described below.

The intermediate connection structure 200 may include one or more intermediate vias 223a and 223b (or a first intermediate via 223a and a second intermediate via 223b) configured to connect a lower connection structure 110 to an upper connection structure 400. In some embodiments, the intermediate connection structure 200 may further include one or more intermediate insulating layers 221a and 221b (a first intermediate insulating layer and a second intermediate insulating layer 221b) through which the one or more intermediate vias 223a and 223b pass. In some embodiments, the intermediate connection structure 200 may further include a plurality of intermediate pattern layers 222a, 222b, and 222c (a first intermediate pattern layer 222a, a second intermediate pattern layer 222b, and a third intermediate pattern layer 222c) which are buried in the one or more intermediate insulating layers 221a and 221b or disposed on the intermediate insulating layers 221a and 221b and connected to each other by the one or more intermediate vias 223a and 223b. For example, the intermediate connection structure 200 may include a first intermediate pattern layer 222a on the upper surface of the lower connection structure 110, a first intermediate insulating layer 221a on the upper surface of the first intermediate pattern layer 222a and the upper surface of the lower connection structure 110, a first intermediate via 223a passing through the first intermediate insulating layer 221a (a first intermediate via 223a and a second intermediate via 223b). The one or more intermediate vias 223a and 223b and the plurality of intermediate pattern layers 222a, 222b, and 222c may provide an electrical path for connecting the lower connection structure 110 to the upper connection structure 400.

For example, the intermediate connection structure 200 may include a first intermediate pattern layer 222a on the upper surface of the lower connection structure 110, a first intermediate insulating layer 221a on the upper surface of the first intermediate pattern layer 222a and the upper surface of the lower connection structure 110, a first intermediate via 223a passing through the first intermediate insulating layer 221a and coming into contact with the upper surface of the first intermediate pattern layer 222a, a second intermediate pattern layer 222b on the upper surface of the first intermediate via 223a and the upper surface of the first intermediate insulating layer 221a, a second intermediate insulating layer 221b on the upper surface of the second intermediate pattern layer 222b and on the first intermediate insulating layer 221a, a second intermediate via 223b passing through the second intermediate insulating layer 221b and coming into contact with the upper surface of the second intermediate pattern layer 222b, and a third intermediate pattern layer 222c on the upper surfaces of the second intermediate via 223b and the upper surface of the second intermediate insulating layer 221b. However, the intermediate connection structure 200 may include more or less than three conductive pattern layers, unlike shown in FIG. 10. The first intermediate via 223a may connect the first intermediate pattern layer 222a to the second intermediate pattern layer 222b and the second intermediate via 223b may connect the second intermediate pattern layer 222b to the third intermediate pattern layer 222c. The first intermediate pattern layer 222a may be in contact with first lower vias 113a and 113b of the lower connection structure 110 and the third intermediate pattern layer 222c may be in contact with an upper redistribution via 414 of the upper connection structure 400.

The characteristics or constituent materials of the plurality of intermediate pattern layers 222a, 222b, and 222c, and the plurality of intermediate insulating layers 221a and 221b illustrated in FIG. 10 are the same as those of the intermediate patterns 211 and 213, the conductive post 212 described above with reference to FIGS. 1 to 3.

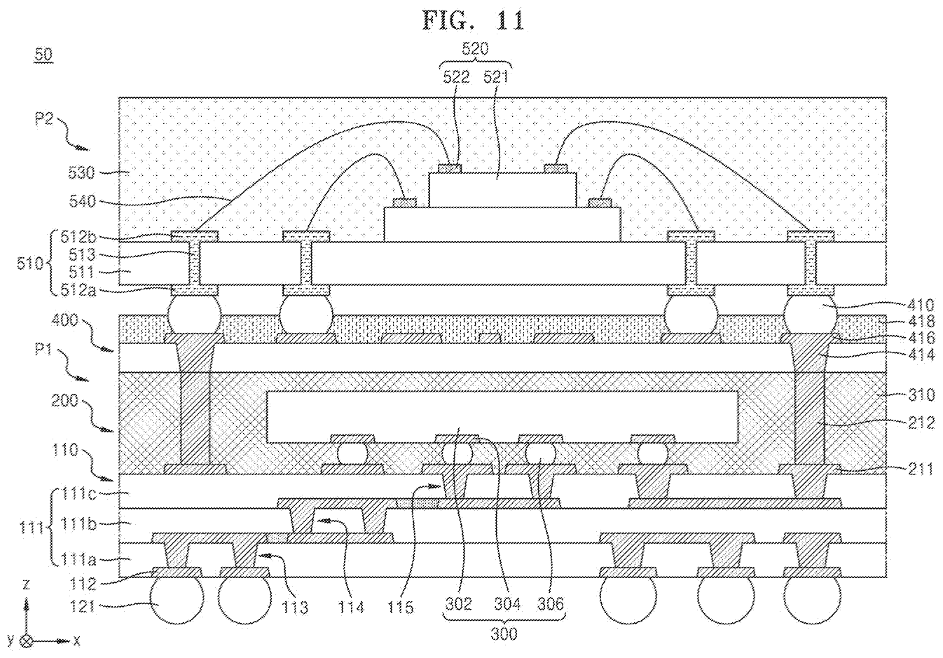

FIG. 11 is a cross-sectional view showing a semiconductor package 50 according to another embodiment.

Referring to FIG. 11, the semiconductor package 50 may include a lower semiconductor package P1, an upper semiconductor package P2 above the lower semiconductor package P1, and a package connection member 410 between the lower semiconductor package P1 and the upper semiconductor package P2. For example, the semiconductor package 50 may be a package on package (POP) type. The lower semiconductor package P1 may include the semiconductor package 10 illustrated in FIG. 1.

The upper semiconductor package P2 may include a connection structure 510 and a second semiconductor chip 520 on the connection structure 510. In some embodiments, the upper semiconductor package P2 may include a plurality of second semiconductor chips 520 stacked on the connection structure 510. In some embodiments, the upper semiconductor package P2 may further include a second encapsulation layer 530 that covers the connection structure 510 and the second semiconductor chip 520.

The connection structure 510 may include, for example, an insulating layer 511, an upper conductive pattern layer 512b on the upper surface of the insulating layer 511, a lower conductive pattern layer 512a on the lower surface of the insulating layer 511, and a via 513 which passes through the insulating layer 511, extends between the upper conductive pattern layer 512b and the lower conductive pattern layer 512a, and connects the upper conductive pattern layer 512b to the lower conductive pattern layer 512a. The connection structure 510 may include a PCB or a redistribution structure. The insulating layer 511 may include, for example, flame retardant 4 (FR4), tetrafunctional epoxy, polyphenylene ether, epoxy/polyphenylene oxide, bismaleimide triazine (BT), thermount, cyanate ester, polyimide, or a combination thereof. Each of the upper conductive pattern layer 512b, the lower conductive pattern layer 512a, and the via 513 may include a conductive material that includes, for example, copper (Cu), gold (Au), silver (Ag), nickel (Ni), tungsten (W), aluminum (Al), or a combination thereof.

The second semiconductor chip 520 may include a body 521 and a chip pad 522 on the upper surface of the body 521. The body 521 may include a substrate and an integrated circuit, and the integrated circuit may be on the upper surface of the second semiconductor chip 520. For example, the active surface of the second semiconductor chip 520 may include the upper surface of the second semiconductor chip 520. The second semiconductor chip 520 may be connected to the upper conductive pattern layer 512b of the connection structure 510 through a wire 540. In another embodiment, the chip pad 522 of the second semiconductor chip 520 may be on the lower surface of the second semiconductor chip 520, and the integrated circuit of the body 521 of the second semiconductor chip 520 may be on the lower surface of the second semiconductor chip 520. For example, the active surface of the second semiconductor chip 520 may include the lower surface of the second semiconductor chip 520. The second semiconductor chip 520 may be connected to the upper conductive pattern layer 512b of the connection structure 510 through bumps or pillars.

In some embodiments, the integrated circuit of the body 302 of the first semiconductor chip 300 of the lower semiconductor package P1 may include a logic circuit, and the integrated circuit of the body 521 of the second semiconductor chip 520 of the upper semiconductor package P2 may include a memory circuit. The second encapsulation layer 530 may include, for example, an epoxy resin, a silicone resin, or a combination thereof. The second encapsulation layer 530 may include, for example, an epoxy mold compound.

The package connection member 410 may be between the lower conductive pattern layer 512a of the connection structure 510 of the upper semiconductor package P2 and an upper redistribution pad 416 of an upper connection structure 400 of the lower semiconductor package P1. The package connection member 410 may connect the lower conductive pattern layer 512a of the connection structure 510 of the upper semiconductor package P2 to the upper redistribution pad 416 of the upper connection structure 400 of the lower semiconductor package P1. An upper protective layer 418 of the lower semiconductor package P1 may expose a portion of the upper redistribution pad 416 that is in contact with the package connection member 410 and may cover the remaining portion of the upper redistribution pad 416. The package connection member 410 may include a conductive material that includes, for example, tin (Sn), lead (Pb), silver (Ag), copper (Cu), or a combination thereof. The package connection member 410 may be formed from, for example, a solder ball.

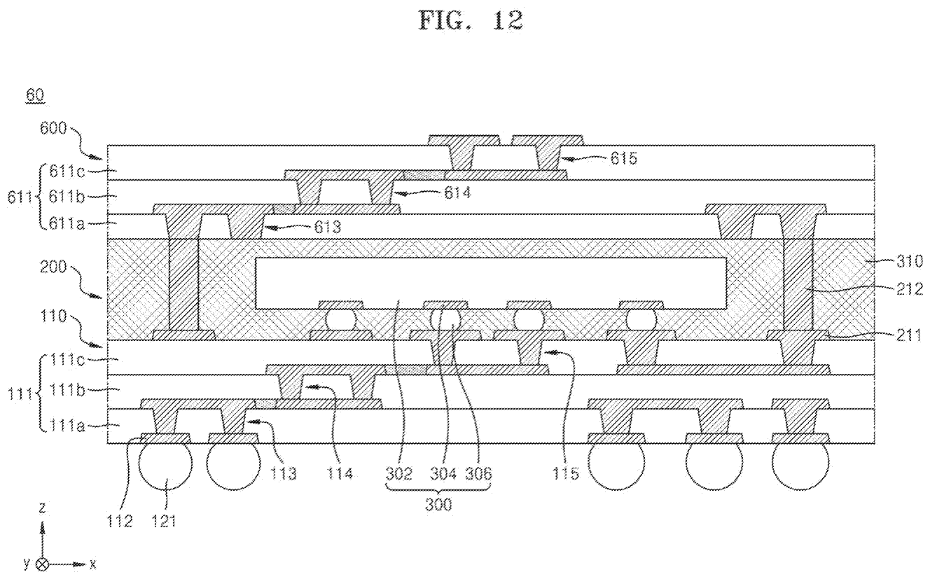

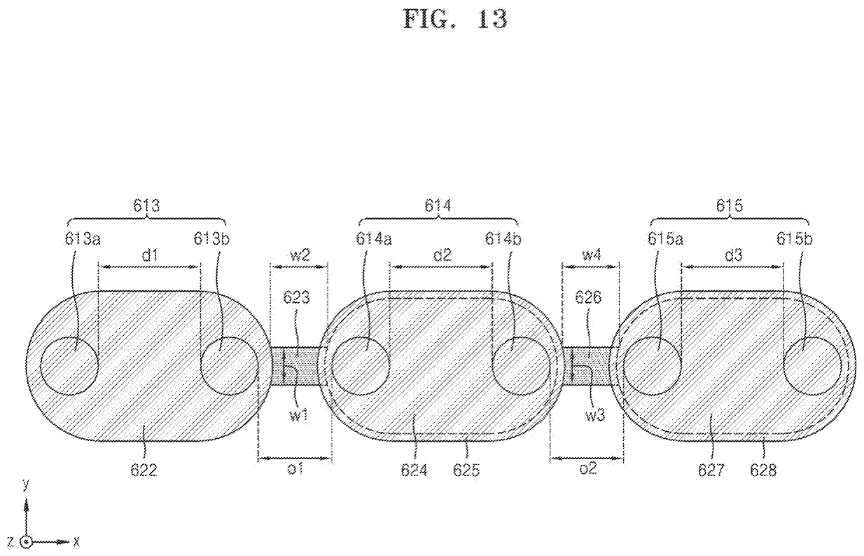

FIG. 12 is a cross-sectional view showing a semiconductor package 60 according to another embodiment. FIG. 13 is a plan view in which a portion of an upper connection structure 600 of the semiconductor package 60 illustrated in FIG. 12 is viewed in the vertical direction.

The semiconductor package 60 illustrated in FIG. 12 may be the same as or similar to the semiconductor package 10 illustrated in FIG. 1, except that the upper connection structure 600 has a different structure. Therefore, repeated descriptions of the components illustrated in FIG. 1 are omitted.

Referring to FIGS. 12 and 13, the semiconductor package 60 according to an embodiment may include an upper connection structure 600 that is on an encapsulation layer 310 for sealing a first semiconductor chip 300. The upper connection structure 600 may be configured to connect a second semiconductor chip, which may be on the upper connection structure 600, to the first semiconductor chip 300. The upper connection structure 600 may include one or more upper insulating layers 611a, 611b, and 611c (a first upper insulating layer 611a, a second upper insulating layer 611b, and a third upper insulating layer 611c), one or more upper redistribution pads 622, 624, 625, 627, and 628 (a first upper pad 622, a second upper pad 624, a third upper pad 625, a fourth upper pad 627, and a fifth upper pad 628) on the one or more upper insulating layers 611a, 611b, and 611c, and one or more upper vias 613a, 613b, 614a, 614b, 615a, and 615b (first upper vias 613a and 613b, second upper vias 614a and 614b, and third upper vias 615a, and 615b) passing through the one or more upper insulating layers 611a, 611b, and 611c and coming into contact with the one or more upper redistribution pads 622, 624, 625, 627, and 628. The one or more upper redistribution pads 622, 624, 625, 627, and 628 and the one or more upper vias 613a, 613b, 614a, 614b, 615a, and 615b may provide an electrical path for connecting the first semiconductor chip 300 to the semiconductor chip that may be on the upper connection structure 600. The upper connection structure 600 may include a redistribution structure or a PCB.

Hereinafter, the upper connection structure 600 is described in more detail. However, the structure of the upper connection structure 600 illustrated in FIGS. 12 and 13 is substantially the same as the lower connection structure 110 illustrated in FIGS. 1 to 3, and thus, a detailed description thereof is omitted.

As illustrated in FIGS. 12 and 13, the upper connection structure 600 may include a first upper via array 613, a second upper via array 614, and a third upper via array 615, which have different vertical levels.

The first upper via array 613 includes a plurality of first upper vias 613a and 613b arranged in a first direction (x direction), the second upper via array 614 includes a plurality of second upper vias 614a and 614b arranged in the first direction (x direction), and the third upper via array 615 includes a plurality of third upper vias 615a and 615b arranged in the first direction (x direction). The drawing illustrates that two first to third upper vias 613a, 613b, 614a, 614b, 615a, and 615b provided in each of the first to third upper via arrays 613, 614, and 615. However, embodiments are not limited thereto, and according to an embodiment, three or more upper vias may be provided in each of the first to third upper via arrays 613, 614, and 615.

The first to third upper vias 613a, 613b, 614a, 614b, 615a, and 615b may be formed respectively through the upper insulating layers 611a, 611b, and 611c. Here, materials included in the first to third upper vias 613a, 613b, 614a, 614b, 615a, and 615b and the upper insulating layers 611a, 611b, and 611c may substantially be the same as materials included in the lower vias 113a, 113b, 114a, 114b, 115a, and 115b and the lower insulating layers 111a, 111b, and 111c illustrated in FIGS. 1 to 3.

The second upper via array 614 may be offset in the first direction (x direction) to not overlap the first upper via array 613 in a third direction (z direction). The first upper via array 613 and the second upper via array 614 having different vertical levels may be offset from each other by a first offset distance o1. During a forming process, the first upper via array 613, the second upper via array 614, the first upper pad 622 may have curved and stepped portions on a horizontal plane. When the first upper via array 613 and the second upper via array 614 are formed vertically overlapping each other with the first upper pad 622 therebetween, a peeling phenomenon may occur at the interface with the first upper insulating layer 611a and the second upper insulating layer 611b due to the accumulation of the curved and stepped portions of the first upper via array 613, the second upper via array 614, and the first upper pad 622. Also, open/short circuit failures may occur between the first upper via array 613, the second upper via array 614, and the first upper pad 622. Therefore, the first upper via array 613 and the second upper via array 614 are spaced apart from each other by the first offset distance o1, to prevent the peeling and open/short circuit failures from occurring at the interface.

A distance d1 between a pair of first upper vias 613a and 613b adjacent to each other among the plurality of first upper vias 613a and 613b may be greater than the first offset distance o1 by which the second upper via array 614 is offset from the first upper via array 613 in the first direction (x direction). The first offset distance o1 by which the second upper via array 614 is offset from the first upper via array 613 in the first direction (x direction) may be about 10 micrometers to about 20 millimeters.

Similarly, the third upper via array 615 may be offset in the first direction (x direction) so as not to overlap the first upper via array 613 and the second upper via array 614 in the third direction (z direction). The second upper via array 614 and the third upper via array 615 having different vertical levels may be offset from each other by a second offset distance o2.

The upper connection structure 600 may include a first upper pad 622 covering an entire area of the upper surface of the first upper via array 613, a second upper pad 624 covering an entire area of the lower surface of the second upper via array 614, a third upper pad 625 covering an entire area of the upper surface of the second upper via array 614, a fourth upper pad 627 covering an entire area of the lower surface of the third upper via array 615, and a fifth upper pad 628 covering an entire area of the upper surface of the third upper via array 615. The plurality of upper pads 622, 624, 625, 627, and 628 may have substantially the same configurations and functions as the plurality of lower pads 122, 124, 125, 127, and 128 described above with reference to FIGS. 1 to 3.

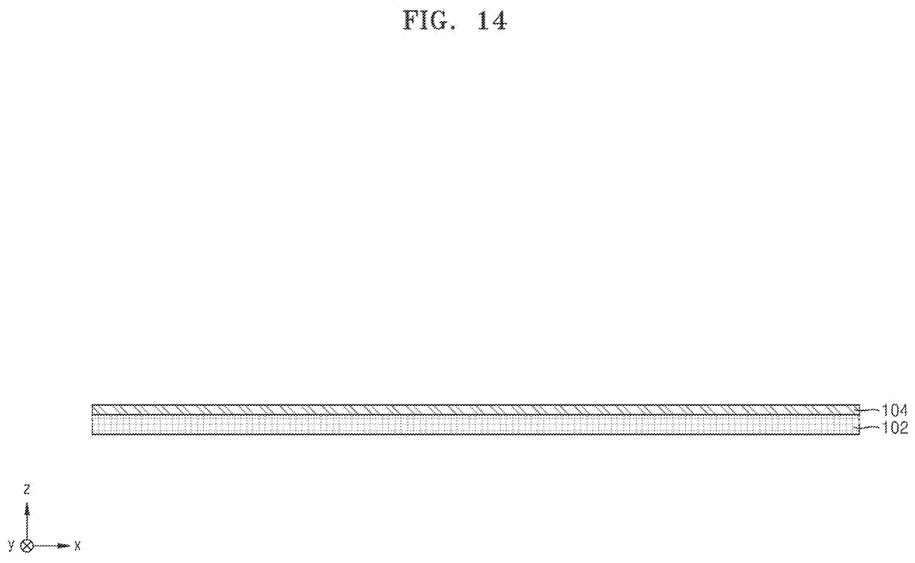

FIGS. 14 to 20 are cross-sectional views illustrating a manufacturing process of the semiconductor package 10 illustrated in FIGS. 1 to 3.

Referring to FIG. 14, a method of manufacturing the semiconductor package 10 according to the inventive concept may include preparing a carrier substrate 102 to which a release film 104 is attached.

The carrier substrate 102 may include any material having stability against a baking process, an etch process, and the like. When the carrier substrate 102 is to be separated and removed later by laser ablation, the carrier substrate 102 may include a light-transmitting substrate. According to an embodiment, when the carrier substrate 102 is to be separated and removed later by heating, the carrier substrate 102 may include a heat-resistant substrate.

In an embodiment, the carrier substrate 102 may include a glass substrate. Also, in another embodiment, the carrier substrate 102 may include heat-resistant organic polymer materials, such as polyimide (PI), polyetheretherketone (PEEK), polyethersulfone (PES), and polyphenylene sulfide (PPS). However, embodiments are not limited thereto.

The release film 104 may include, for example, a laser reactive layer that may be vaporized by laser irradiation and separated from the carrier substrate 102. The release film 104 may include a carbon-based material layer. For example, the release film 104 may include an amorphous carbon layer (ACL).

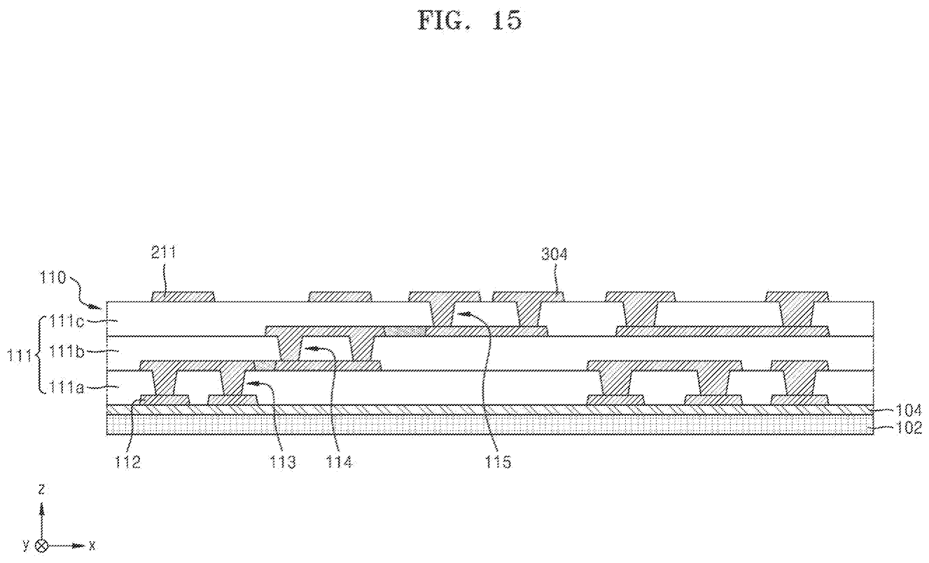

Referring to FIG. 15, the method of manufacturing the semiconductor package 10, may include forming a lower connection structure 110 above the carrier substrate 102 to which the release film 104 is attached. A plurality of lower via arrays 113, 114, and 115 may be formed through a deposition process or a plating process after holes are formed in lower insulating layers 111a, 111b, and 111c, respectively. The deposition process may include a process selected from among physical vapor deposition (PVD), chemical vapor deposition (CVD), and atomic layer deposition (ALD).

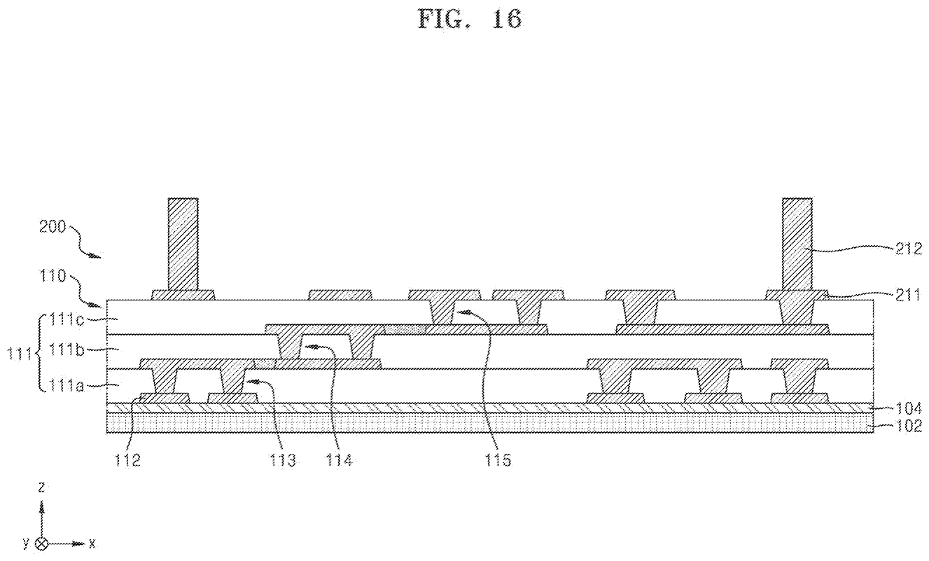

Referring to FIG. 16, the method of manufacturing the semiconductor package 10, may include forming an intermediate connection structure 200 on the lower connection structure 110. Conductive posts 212 may be disposed on the lower connection structure 110. The conductive posts 212 may be buried in an intermediate insulating layer 221. In an embodiment, the conductive posts 212 may be provided adjacent to and surround a space in which a first semiconductor chip 300 is to be located. A hole passing through the intermediate insulating layer 221 may be formed between the conductive posts 212. The hole passing through the intermediate insulating layer 221 may be formed by, for example, mechanical drilling, laser drilling, sand blasting, dry etching, and/or wet etching.

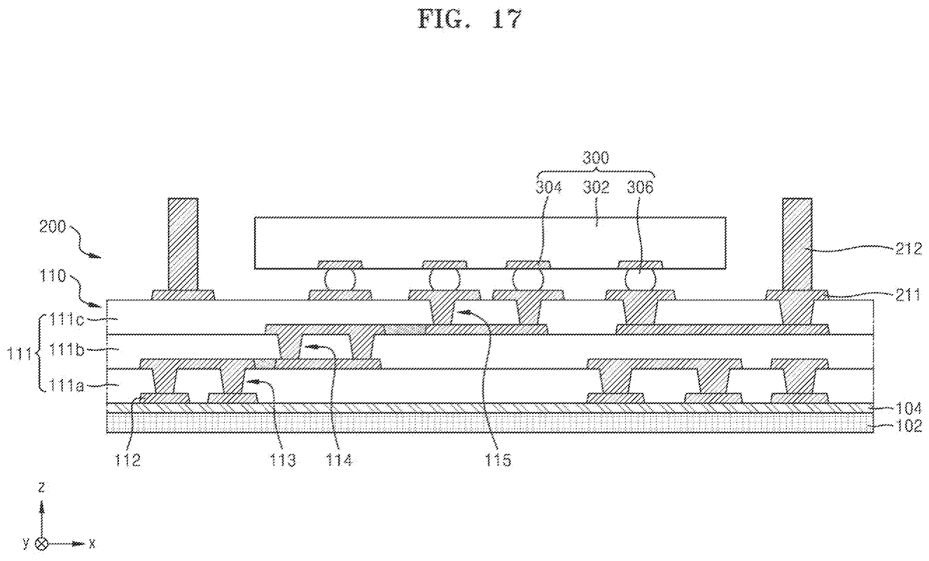

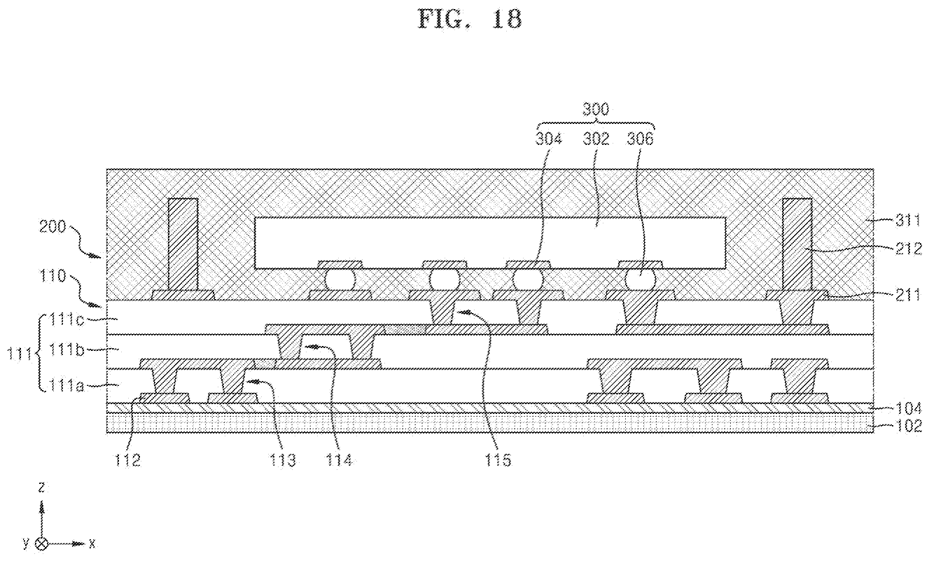

Referring to FIGS. 17 and 18, the method of manufacturing the semiconductor package 10, may include attaching a body 302 of the first semiconductor chip 300 to a chip pad 304. Subsequently, a first encapsulation layer 310 covering the first semiconductor chip 300 and the intermediate connection structure 200 may be formed. The first encapsulation layer 310 may be formed by a known method. For example, the first encapsulation layer 310 may be formed by laminating a sealing material onto the upper surface of the first semiconductor chip 300 and the upper surface of the intermediate connection structure 200 and then curing the sealing material.

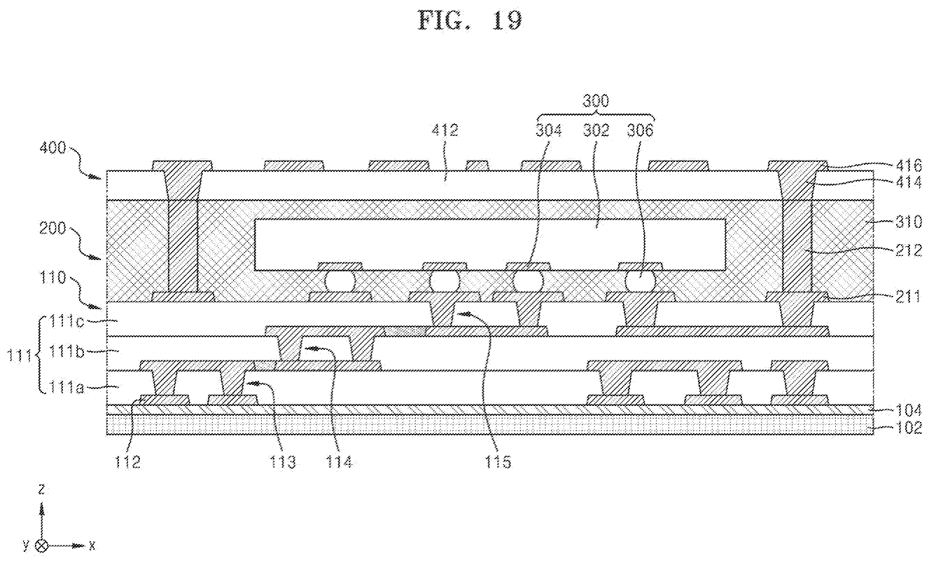

Referring to FIG. 19, the method of manufacturing the semiconductor package 10, may include forming an upper connection structure 400 on the intermediate connection structure 200 and the first encapsulation layer 310. An upper redistribution via 414 may be formed through a deposition process or a plating process after a hole is formed in an upper redistribution insulating layer 412. The deposition process may include a process selected from among PVD, CVD, and ALD.

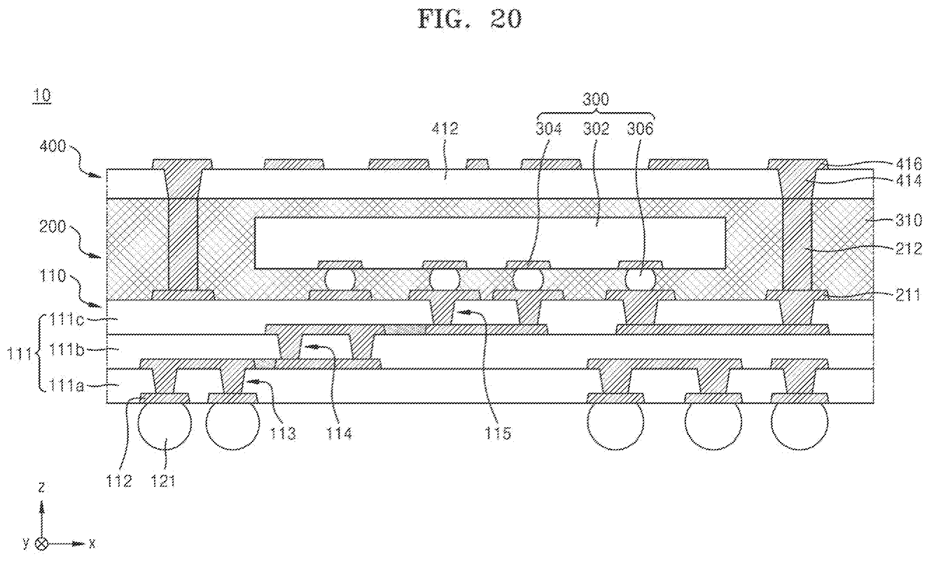

Referring to FIG. 20, the method of manufacturing the semiconductor package 10, may include attaching an external connection terminal 121 onto a lower pad 112 of the lower connection structure 110. The method may include removing the carrier substrate 102 before the external connection terminal 121 is attached to the lower pad 112. In an embodiment, the carrier substrate 102, to which the release film 104 is attached, may be separated from the result of FIG. 17. For example, in order to separate the carrier substrate 102, the release film 104 may be irradiated with a laser beam or heated. After the carrier substrate 102 is separated, the external connection terminal 121 may be attached to the exposed lower pad 112. The external connection terminal 121 may include, for example, a solder ball or a bump.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a semiconductor chip;
a connection structure below the semiconductor chip and electrically connected to the semiconductor chip; and
an external connection terminal below the connection structure,
wherein the connection structure comprises:
a first via array comprising a plurality of first vias in a first direction;
a second via array above the first via array and comprising a plurality of second vias in the first direction; and
a first pad between the first via array and the second via array and on upper surfaces of the plurality of the first vias,
wherein the second via array is offset from the first via array in the first direction and does not overlap the first via array in a vertical direction.

2. The semiconductor package of claim 1, wherein the first via array is integrally formed with the first pad.

3. The semiconductor package of claim 1, wherein a distance between first vias adjacent to each other among the plurality of first vias is greater than a distance by which the second via array is offset from the first via array in the first direction.

4. The semiconductor package of claim 1, wherein a diameter of each of the plurality of first vias and a diameter of each of the plurality of second vias decreases towards the external connection terminal.

5. The semiconductor package of claim 1, wherein the connection structure further comprises a second pad between the first via array and the second via array and on lower surfaces of the plurality of the second vias,
wherein the first pad is on the upper surfaces of the plurality of first vias, and
wherein the second pad is on the lower surfaces of the plurality of second vias.

6. The semiconductor package of claim 1, further comprising a lower pad below the first via array and electrically connected to the external connection terminal,
wherein the lower pad is in contact with the first via array.

7. The semiconductor package of claim 1, wherein the connection structure further comprises:
a third via array above the second via array and comprising a plurality of third vias in the first direction; and
a third pad between the second via array and the third via array and on upper surfaces of the plurality of the second vias,
wherein the third via array is offset from the second via array in the first direction and does not overlap the second via array in the vertical direction.

8. The semiconductor package of claim 7, further comprising an upper pad on the third via array and electrically connected to the semiconductor chip,
wherein the upper pad is on upper surfaces of the plurality of third vias.

9. The semiconductor package of claim 7, wherein a distance between second vias adjacent to each other among the plurality of second vias is greater than a distance by which the third via array is offset from the second via array in the first direction.

10. The semiconductor package of claim 7, wherein the third via array overlaps at least a portion of the first via array in the vertical direction.

11. The semiconductor package of claim 1, wherein a distance by which the second via array is offset from the first via array in the first direction is 10 micrometers to 20 millimeters.

12. A semiconductor package comprising:
a semiconductor chip; and
a connection structure below the semiconductor chip and electrically connected to the semiconductor chip,
wherein the connection structure comprises:
a plurality of first vias in a first direction;
a plurality of second vias in the first direction above the plurality of first vias;
a first pad between the plurality of first vias and the plurality of second vias and on upper surfaces of the plurality of first vias;
a second pad between the plurality of first vias and the plurality of second vias and on lower surfaces of the plurality of second vias; and
a redistribution pattern between the first pad and the second pad in the first direction,
wherein the plurality of second vias are offset from the plurality of first vias in the first direction and does not overlap the plurality of first vias in a vertical direction.

13. The semiconductor package of claim 12, wherein the redistribution pattern is integrally formed with the first pad and the second pad.

14. The semiconductor package of claim 12, wherein a material of the redistribution pattern is same as a material of the first pad and a material of the second pad.

15. The semiconductor package of claim 12, wherein a width of the redistribution pattern in the first direction is greater than a width of the redistribution pattern in a second direction perpendicular to the first direction.

16. The semiconductor package of claim 12, wherein the first pad is on the upper surfaces of the plurality of first vias, and
wherein the second pad is on the lower surfaces of the plurality of second vias.

17. The semiconductor package of claim 12, wherein a width of the redistribution pattern in the first direction is less than a distance between first vias adjacent to each other among the plurality of first vias and is less than a width of the first pad in the first direction.

18. A semiconductor package comprising:
a semiconductor chip;
a connection structure below the semiconductor chip and electrically connected to the semiconductor chip;
a solder ball below the connection structure;
a pad below the semiconductor chip and electrically connected to the semiconductor chip;
a conductive post adjacent to the semiconductor chip; and
an encapsulation layer on the semiconductor chip and the conductive post,
wherein the connection structure comprises:
a first via array comprising a pair of first vias in a first direction;
a second via array above the first via array and comprising a pair of second vias in the first direction;
a first pad between the first via array and the second via array, integrally formed with upper surfaces the pair of first vias, and extending in the first direction;
a second pad between the first via array and the second via array and in contact with lower surfaces of the pair of second vias; and
a redistribution insulating layer in which the first via array, the second via array, the first pad, and the second pad are buried,
wherein the second via array is offset from the first via array in the first direction and does not overlap the first via array in a vertical direction,
wherein the upper surface of the first pad and the upper surface of the second pad are at the same vertical level, and
wherein a distance between the pair of first vias is greater than a distance by which the second via array is offset from the first via array in the first direction.

19. The semiconductor package of claim 18, wherein the connection structure further comprises a redistribution pattern between the first pad and the second pad in the first direction,
wherein the redistribution pattern is integrally formed with the first pad and the second pad and a material of the redistribution pattern is same as a material of the first pad and a material of the second pad, and
wherein a width of the redistribution pattern in the first direction is greater than a width of the redistribution pattern in a second direction perpendicular to the first direction.

20. The semiconductor package of claim 18, wherein the connection structure further comprises:
a third via array above the second via array and comprising a plurality of third vias in the first direction; and
a third pad between the second via array and the third via array and on upper surfaces of the plurality of the second vias,
wherein the third via array is offset from the second via array in the first direction and does not overlap the second via array in the vertical direction,
wherein the third via array is configured to provide a movement path of a power signal to operate the semiconductor chip or a movement path of a signal of the semiconductor chip.
